(19) United States
(12) Patent Application Publication
(10) Pub. No.: US 2009/0032288 A1
(43) Pub. Date: Feb. 5, 2009

(54) CONNECTOR AND PRINTED CIRCUIT BOARD

(76) Inventors: Tien-Ko LAI, Taipei Hsien (TW); Muh-Jin Uang, Taipei Hsien (TW); Chia-Cheng Chang, Taipei Hsien (TW)

Correspondence Address: BIRCH STEWART KOLASCH & BIRCH, PO BOX 747, FALLS CHURCH, VA, 22040-0747, US

(21) Appl. No.: 12/203,770

(22) Filed: Sep. 3, 2008

Related U.S. Application Data
(62) Division of application No. 11/882,536, filed on Aug. 2, 2007.

(51) Int. Cl. H05K 1/00

(52) U.S. Cl. 174/250

(57) ABSTRACT

A connector including a first pin and a second pin is disclosed. The first pin includes a first side including a first protrudent part. The second pin includes a second side facing the first side. The first protrudent part approaches the second side.

This application is a Divisional of co-pending application Ser. No. 11/882,536, filed on Aug. 2, 2007, the entire contents of which are hereby incorporated by reference and for which priority is claimed under 35 U.S.C. §120.

### BACKGROUND OF THE INVENTION

1. Field of the Invention

The invention relates to a connector and a printed circuit board (PCB), and more particularly to a connector and a PCB for discharging electrostatic stress.

2. Description of the Related Art

FIG. 1 is a schematic diagram of a conventional printed circuit board. Printed circuit board (PCB) 100 comprises a pad group 110, traces 120, 121, and an integrated circuit (IC) 130. Pad group 110 comprises pads 111-113 for welding with an input/output connector (not shown). Pad 112 electrically connects IC 130 via trace 120. Pad 113 is grounded.

Electrostatic charge is easily accumulated in human bodies due to friction or other causes. When a person having a large amount of electrostatic charge touches a cable connecting an input/output connector, the accumulated electrostatic charge enters IC 130 from pad 112 and trace 120. Thus, IC 130 is damaged.

FIG. 2 is an equivalent diagram of the convention PCB. Symbol Z₂₁ represents the impedance of the first half of trace 120. The first half of trace 120 approaches pad group 110. Symbol Z₂₂ represents the impedance of the second half of trace 120. The second half of impedance of trace 120 approaches IC 130. Symbol Z₂₃ represents the impedance of IC 130. Symbol Z₂₄ represents the impedance of trace 121.

When an electrostatic event occurs in pad 112, electrostatic current I_{ESD} is generated. Voltage V_{gen} of point A is expressed by the following equation (1):

V_{gen}=(Z₂₃+Z₂₄)×I_{ESD} (1)

If the electrostatic charge entering from the outside is not properly taken care of, the ICs welded in the PCB are damaged. Thus, the computer comprising the damaged ICs crashes.

### BRIEF SUMMARY OF THE INVENTION

Connectors are provided. An exemplary embodiment of a connector comprises a first pin and a second pin. The first pin comprises a first side comprising a first protrudent part. The second pin comprises a second side facing the first side. The first protrudent part approaches the second side.

Printed circuit boards are also provided. An exemplary embodiment of a printed circuit board comprises a first pad and a second pad. The first pad comprises a first side comprising a first protrudent part. The second pad comprises a second side facing the first side. The first protrudent part approaches the second side

A detailed description is given in the following embodiments with reference to the accompanying drawings.

### BRIEF DESCRIPTION OF THE DRAWINGS

The invention can be more fully understood by referring to the following detailed description and examples with references made to the accompanying drawings, wherein:

FIG. 1 is a schematic diagram of a conventional printed circuit board;

FIG. 2 is an equivalent diagram of the conventional printed circuit board;

FIG. 3a is a schematic diagram of an exemplary embodiment of a printed circuit board;

FIG. 3b is a schematic diagram of an exemplary embodiment of protrudent parts;

FIG. 4 is an equivalent diagram of FIG. 3a; and

FIG. 5 is a schematic diagram of an exemplary embodiment of a connector.

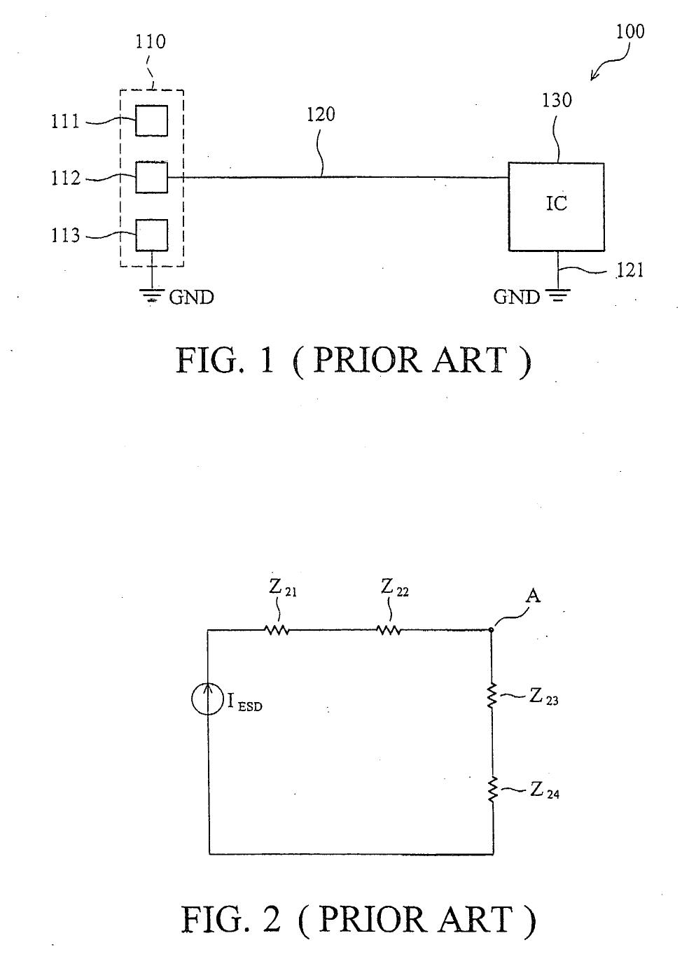

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

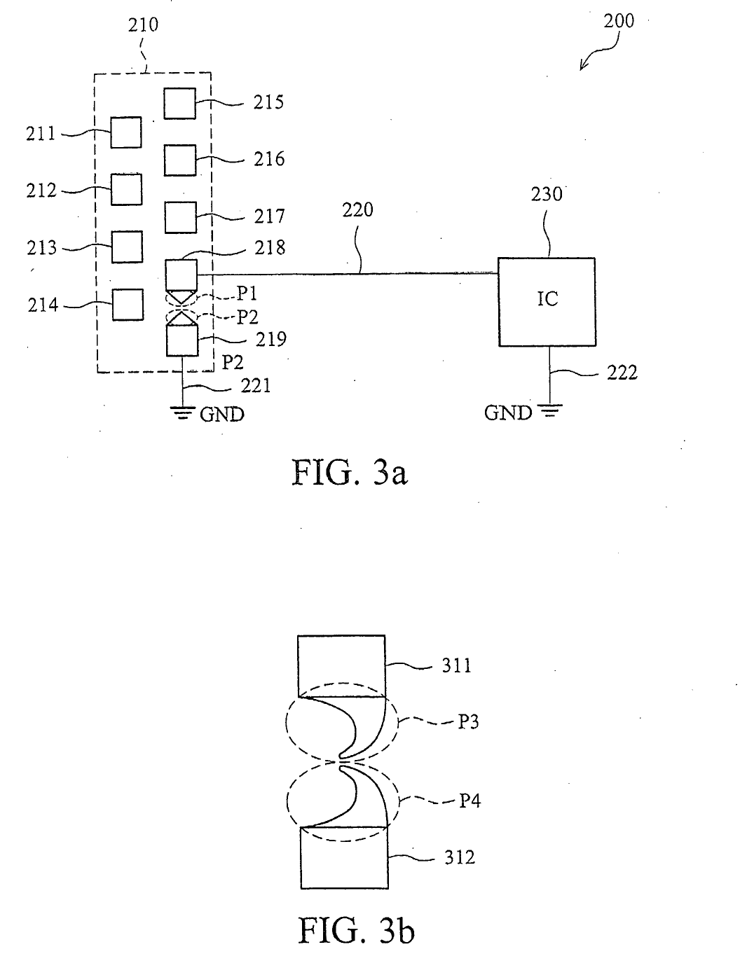

FIG. 3a is a schematic diagram of an exemplary embodiment of a printed circuit board. Printed circuit board (PCB) 200 comprises a pad group 210, traces 220-222, and an IC 230. Pad group 210 comprises pads 211-219 for welding with a connector (not shown). When the pins of the connector is welded to pads 211-219, if a connection line is utilized for connecting an external peripheral device and the connector, data can be transmitted between the external peripheral device and IC 230. In this embodiment, shapes of pads 211-219 are squares, but the disclosure is not limited thereto. In some embodiments, the shapes of pads 211-219 are circular or other shapes.

Pad 219 receives a power signal, such as a grounding signal. Pad 218 receives a data signal. Pad 218 comprises a side adjoining pad 219. The side of pad 218 comprises protrudent part P1. Pad 219 comprises a side adjoining pad 218. The side of pad 219 comprises protrudent part P2. Protrudent part P1 faces and approaches protrudent part P2. In this embodiment, the shapes of protrudent parts P1 and P2 are triangles, but are not limited to these. In some embodiments, only pad 218 receiving the data signal comprises a protrudent part P1 facing pad 219. Pad 219 does not comprise protrudent part P2. In one embodiment, only pad 219 receiving the power signal comprises protrudent part P2 and pad 218 receiving the data signal does not comprises protrudent part P1, wherein protrudent part P2 faces pad 218.

FIG. 3b is a schematic diagram of an exemplary embodiment of protrudent parts. The side of pad 311, facing pad 312, comprises protrudent part P3. The side of pad 312, facing pad 311, comprises protrudent part P4. Protrudent part P3 faces and approaches protrudent part P4. In this embodiment, protrudent parts P3 and P4 are arcs.

Referring to FIG. 3a, when a data signal is transmitted from an external peripheral device to IC 230 via pad 218, if an electrostatic event occurs in pad 218, the electrostatic current is released from protrudent parts P1, P2, pad 219, and trace 221 to ground. Since electrostatic current is immediately released by protrudent parts P1 and P2, trace 220 and IC 230 are not affected by the electrostatic current.

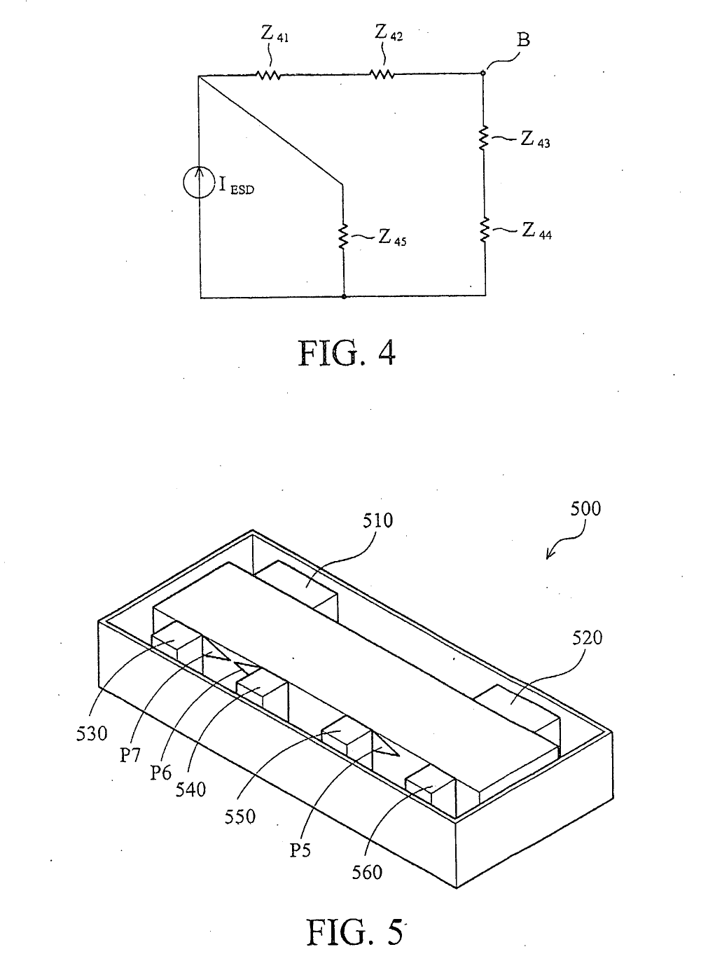

FIG. 4 is an equivalent diagram of FIG. 3a. Symbol Z₄₁ represents the impedance of the first half of trace 220. Symbol Z₄₂ represents the impedance of the second half of trace 220. Symbol Z₄₃ represents the impedance of IC 230. Symbol Z₄₄ represents the impedance of trace 222. Symbol Z₄₅ represents the impedance between protrudent part P1 and the ground.

When an electrostatic event occurs in pad 218, electrostatic current I_{ESD} is generated. Voltage V_{new} of point B is expressed by the following equation (2):

$${V}_{new} = ( {Z}_{43} + {Z}_{44} ) \times \frac{{I}_{ESD} \times {Z}_{45}}{( {Z}_{41} + {Z}_{42} + {Z}_{43} + {Z}_{44} + {Z}_{45} )} \qquad ( 2 )$$

Compared with equation (1), assuming impedances Z₂₃ and Z₂₄ equal to impedances Z₄₃ and Z₄₄, respectively. After calculating, voltage V_{new} is less than voltage V_{gen}. Thus, the effect of the electrostatic event is reduced through protrudent parts P1 and P2 of pads 218 and 219. When the electrostatic voltage is higher, impedance Z₄₅ is reduced, thus, the electrostatic effect is reduced. Impedance Z₄₅ bases on the shapes of protrudent parts P1 and P2 and a distance between protrudent parts P1 and P2. Electrostatic tolerance of PCB 200 is controlled when protrudent parts P1 and P2 are controlled. Additionally, a region connecting pad 219 is paved with copper such that other pads may utilize peak discharge to release the electrostatic current to ground.

FIG. 5 is a schematic diagram of an exemplary embodiment of a connector. Connector 500 comprises pins 510-560. In this embodiment, pins 530 and 560 transmit power signals, such as grounding signals. Pins 540 and 550 transmit data signals. The right side of pin 550, approaching pin 560, comprises protrudent part P5 for releasing the electrostatic current. Additionally, the side of pin 540, facing pin 530, comprises protrudent part P6. The side of pin 530, facing pin 540, comprises protrudent part P7. When an electrostatic event occurs in pin 540, the electrostatic current is released via protrudent parts P6 and P7.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A printed circuit board, comprising:
a first pad comprising a first side comprising a first protrudent part; and
a second pad comprising a second side facing the first side, wherein the first protrudent part approaches the second side.

2. The printed circuit board as claimed in claim 1, wherein the second side comprises a second protrudent part approaching the first protrudent part.

3. The printed circuit board as claimed in claim 1, wherein a data signal is transmitted by the first pad and a power signal is transmitted by the second pad.

4. The printed circuit board as claimed in claim 1, wherein the power signal is a grounding signal.

5. The printed circuit board as claimed in claim 1, wherein the shape of the first protrudent part is a first triangle and the shape of the second protrudent part is a second triangle.

6. The printed circuit board as claimed in claim 1, wherein the peak of the first triangle approaches the peak of the second triangle.

7. The printed circuit board as claimed in claim 1, wherein the shape of the first protrudent part is a first arc and the shape of the second protrudent part is a second arc.

8. The printed circuit board as claimed in claim 1, wherein a terminal of the first arc approaches a terminal of the second arc.
